(19) United States
(12) Patent Application Publication
(10) Pub. No.: US 2015/0153155 A1
(43) Pub. Date: Jun. 4, 2015

(54) SPECKLE PATTERN PROCESSING CIRCUIT WITH I2C AND A/B PHASE OUTPUT

(71) Applicant: ANAPEX TECHNOLOGY INC., HSINCHU (TW)

(72) Inventor: TSUNG WEN HUANG, HSINCHU (TW)

(73) Assignee: ANAPEX TECHNOLOGY INC., HSINCHU (TW)

(21) Appl. No.: 14/093,652

(22) Filed: Dec. 2, 2013

(51) Int. Cl. G01B 9/02; G01J 1/44; H01L 27/146

(52) U.S. Cl. CPC G01B 9/02041; H01L 27/14601; G01J 1/44

(57) ABSTRACT

An electronic circuit for calculating image shift in successive images generated by using image invariant optical speckle patterns, with results output as serial I2C or A/B phase signals. The device comprises a laser LED light source, an optical structure, an image detector, an integrated circuit, and a micro-controller. The laser LED light source generates a collimated laser directed at a contact surface through the optical structure. The image detector may capture the speckle patterns from a moving surface. The integrated circuit can perform image shift calculations to determine the shifted distance moved on the surface so as to output the serial I2C or A/B phase signals, which the micro-controller can utilize for movement and location determining applications. Because it is capable of measuring extremely fine changes on scales of one micrometer or less, this invention may be used in surface recognition and precision control applications.

### BACKGROUND OF THE INVENTION

Speckle patterns are spatial patterns which result from interferences of waves of the same frequency but different amplitudes and phases. Due to constructive interference creating brighter spots and destructive interference creating darker spots, the resultant wave would vary in intensity. This effect can be achieved in practice by aiming a light at an uneven surface. This would create scattered lights that can then be collected to create optical speckle patterns via interferences.

This property is one of the discoveries that has been made with laser technology. Originally, the fact that lasers can produce speckle patterns when reflected off an uneven surface is considered to be a flaw. The variable resulting patterns was thought of as noise. Later however, it came to be realized that these variations actually meant that speckle images carry information concerning the surface that produced them. This has led to the development of image invariant speckle pattern capturing technology as a means of imagining a particular surface and its features. An advantage of speckle pattern based comparison technologies is that it can perform localizing and image shift calculations to a precision of one micrometer or even less. These properties allow speckle pattern technology to be used for precision control and movement sensing applications

A typical device making use of the speckle pattern technology is shown in FIG. 1. Such a device would include a laser LED light source (11), an optical structure (12), a contact surface (10), and an image detector (13). The generated laser is directed through the optical structure's conclave lens (121), producing collimated lights which then reach the surface at an incidence angle of theta. The optical structure uses the refraction angle of phi to set up the aperture (122) for collecting scattered light. The conclave lens (123) focuses the result into collimated lights, which goes through the second aperture (124) to be detected by the image detector (13).

FIG. 2 demonstrates how an image invariant speckle capturing technology acquires consecutive images. The collimated laser light hits the contact surface at an incidence angle of theta, while the opposite image detector unit uses the opposite refraction angle of phi to collect scattered light. Because a surface is uneven, the image detector will see light and dark spots as a result of light interference and constructive interference. Thus, given an image of sufficient size, a spectral pattern can be considered as a unique image with identifiable features. Since the resolution of speckle pixels can vary between several to several tens of micrometers, the image detector needs to be capable of functioning at a sufficient speed (for example 5000 frames per second) and outputting control signals for effective practical applications.

### BRIEF SUMMARY OF THE APPLICATION

This invention relates to an electronic circuit design capable of performing high-speed measurements of image shift of image-invariant speckle patterns, and output the results using I2C or A/B phase serial signals, providing a method for high precision control applications. The design consists of a high speed image detector, an image capture unit, an image matcher. By working in parallel, the design can supply outputs to the I2C or A/B phase signals at very high frame rates.

The first objective of this invention is to provide an image detection circuit capable of high speed spectral imaging. The second objective of this invention is a circuit for high speed image matching and image shift calculations. The third objective is to provide an I2C and AB serial output to transmit the image shift value to a backend MCU.

### BRIEF DESCRIPTION OF THE SEVERAL VIEWS OF THE DRAWING

FIG. 1. Implementation of a typical image-invariant speckle pattern capturing device

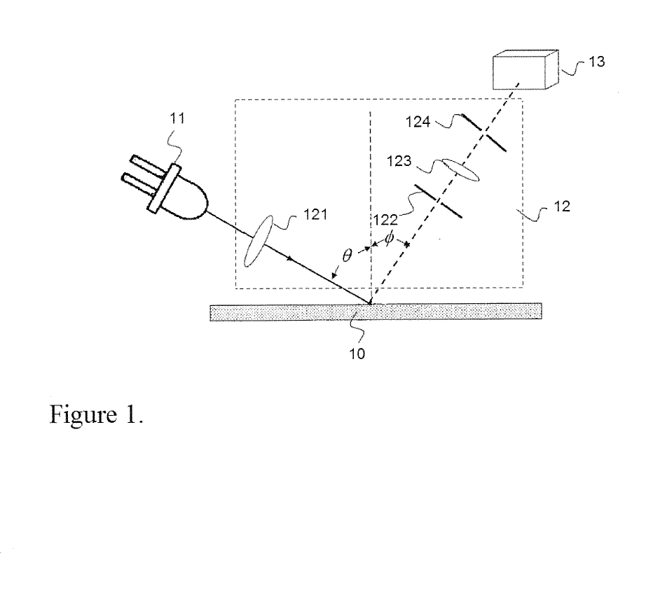

FIG. 2. Consecutive speckle patterns captured while moving a detector

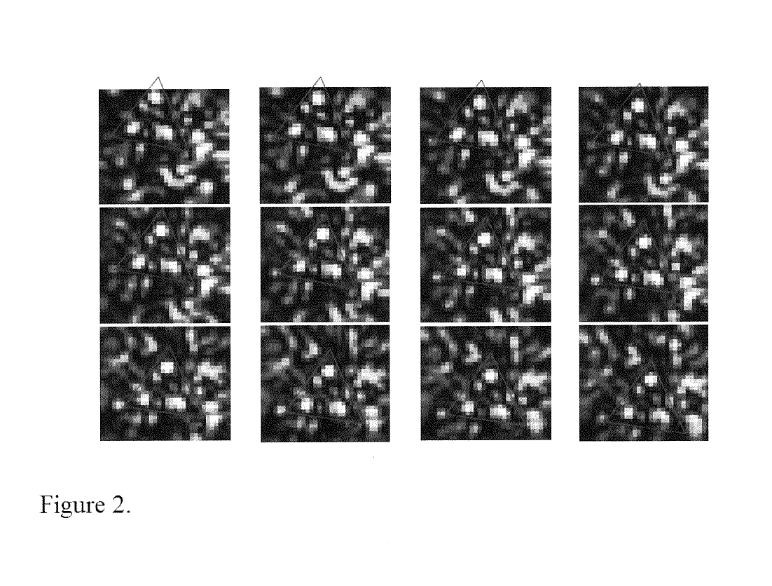

FIG. 3. High speed image detection, capturing and matching unit with serial output

FIG. 4. Implementation of a high speed speckle image detector

FIG. 5. Implementation of a high speed image matching and image shift calculating unit

FIG. 6. Diagram of the serial I2C and A/B phase output signal generator

FIG. 7. Structural diagram of an implementation of the optical device

(0) High speed image detection, capturing and matching unit with serial output
(2) High speed speckle image detector
(3) Image matching and shift calculator unit
(4) Serial signal generator
(10) Contact Surface
(11) Laser LED light source
(12) Optical Device
(13) Microcontroller
(20) Optical Diode Array
(21) Integrator Array
(22) Voltage Sampler Array
(23) Multiplexer
(24) High Speed Analogue to Digital Converter
(26) Grey-scale Image Memory
(31) Image Duplicator
(32) Central Image Memory
(34) Image Matching Unit
(35) Image Shift Accumulator
(40) Serial Signal Generator

### DETAILED DESCRIPTION OF THE INVENTION

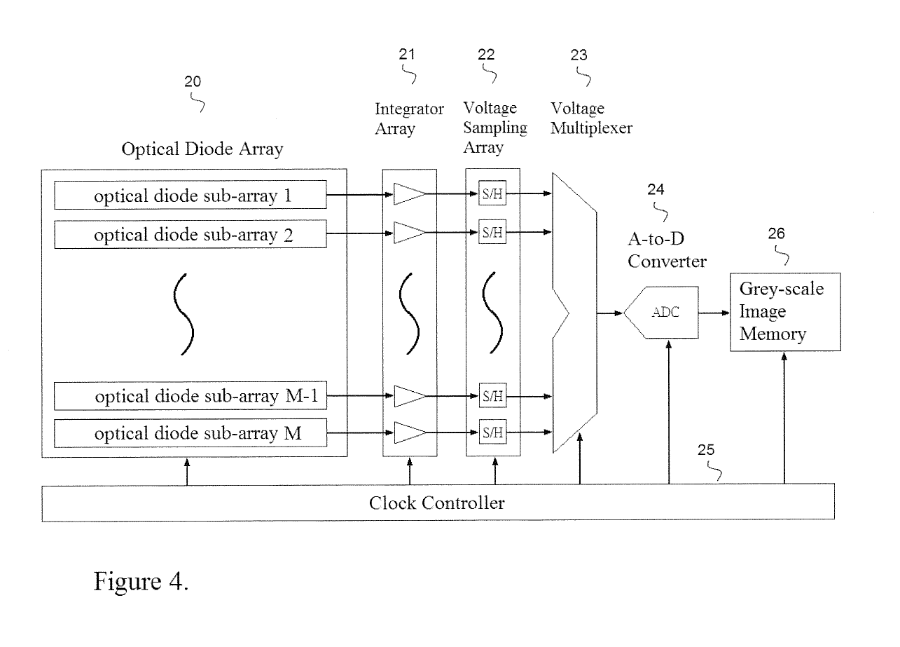

The image detection circuitry (as shown in FIG. 4) of this invention is capable of high speed spectral imaging. It contains an optical diode array (20), an integrator array (21), a voltage sampling array (22), a multiplexer (23), a high speed analogue to digital converter (24), a clock controller (25) and a grey-scale image memory block (26). At the start of each detection period, the clock generator puts every diode in the optical diode array into a reverse bias state. It then turns on the diode one by one, generating a photocurrent within each diode and causing the voltage at the N+ terminals to drop. These N+ terminal voltages are integrated by the integrator array, producing the voltage drop as an output for the voltage sampler to read.

The large number of optical diodes to be read poses an obstacle to high speed image detection. In order to achieve higher speed, therefore, the optical array is arranged as M number of sub-arrays of diodes, placed in parallel. Each sub-array then cycles through its set of diodes for exposure independently, thus achieving an overall speed increase over sequential exposures by a factor of M times. Within each optical sub-array, each diode is exposed, integrated, and sampled in a pace controlled by the clock generator and as a pipeline. The sampled voltages are then converted into 8 bit, 256-level grey-scale digital values. Since the analogue to digital converter operates at a much faster speed than diode exposures are capable of, a multiplexer is deployed to maximize the efficiency. The multiplexer sequentially selects each of the M sets of sampled voltages to be converted into 8 bit digital grey scales. Each of the 256 levels of grey scale values can thus represent a single pixel. There are a total of M*L pixels within a complete image.

The high speed image matching and image shift calculations circuit compares consecutive images by calculating how much distance the second image have moved relative to its preceding one. This is achieved by using an image duplicator (31), a central image memory (32), an image matching circuit (34), a image shift accumulator (35), and a clock signal generator (33). Since the image detector needs to be capable of high speed capturing, this means that the grey-scale image memory's contents are also refreshed within a corresponding time period. For example, a 5000 frames per second image detector would refresh the memory every 0.2 ms. The system thus imposes the same timing constraint on the image matching and image shift calculating operations.

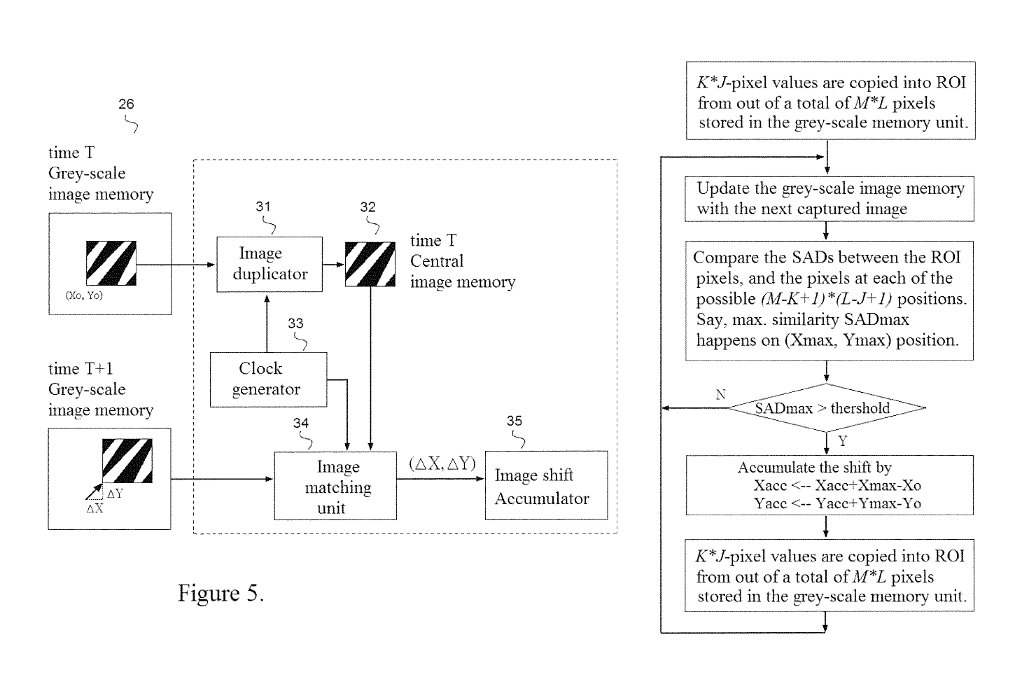

The calculation process is outlined in FIG. 5. First the image duplicator copies K*J pixels from out of a total of M*L pixels stored within the grey-scale memory unit. This block of K*J pixels is then saved into the central image memory (32) as the Region of Interest (ROI), the target against which the next image will be matched to. When the next grey-scale image is updated into the grey-scale memory unit, the image matcher (34) searches for the same ROI in the new image. With this, the image shift can be found from the difference between their coordinates. The potential coordinates at which the ROI can appear at in the new image may be described as (M−K+1)*(L−J+1).

To determine the image shift, therefore, the image matcher compares the sum of absolute differences between the ROI pixels, and the pixels at each of the possible new positions. This is repeated until the image with the highest similarity, SADmax, is found at the coordinate (Xmax, Ymax). If SADmax exceeds the threshold value, then the image at (Xmax, Ymax) is considered to be a successful match and designated as the new ROI. The image shift calculator can thus determine the image shift between the current image of speckle pattern and the previous one. The shift is accumulated in registers for serial output.

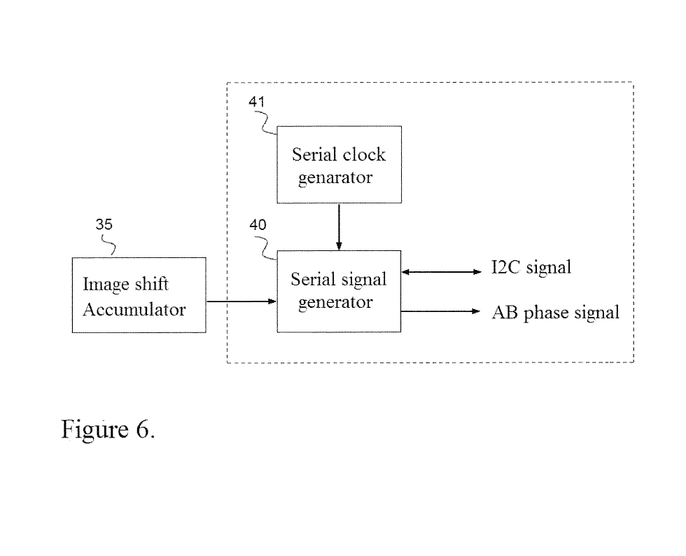

Lastly, the design includes circuitry for providing I2C and AB serial output (FIG. 6) to transmit the image shift value to a backend MCU, which would allow application circuitry to utilize these values for a range of applications. The serial output unit consists of a serial signal generator (40) and a serial clock generator (41). The image matching and shift calculating unit can output the results of its calculations via A/B phase signals, resulting in an input signals for applications where synchronized updates is desired. A second choice is for the circuit to output its results using I2C signals. This provides an alternative for applications which only seek to read image shift values at asynchronous points.

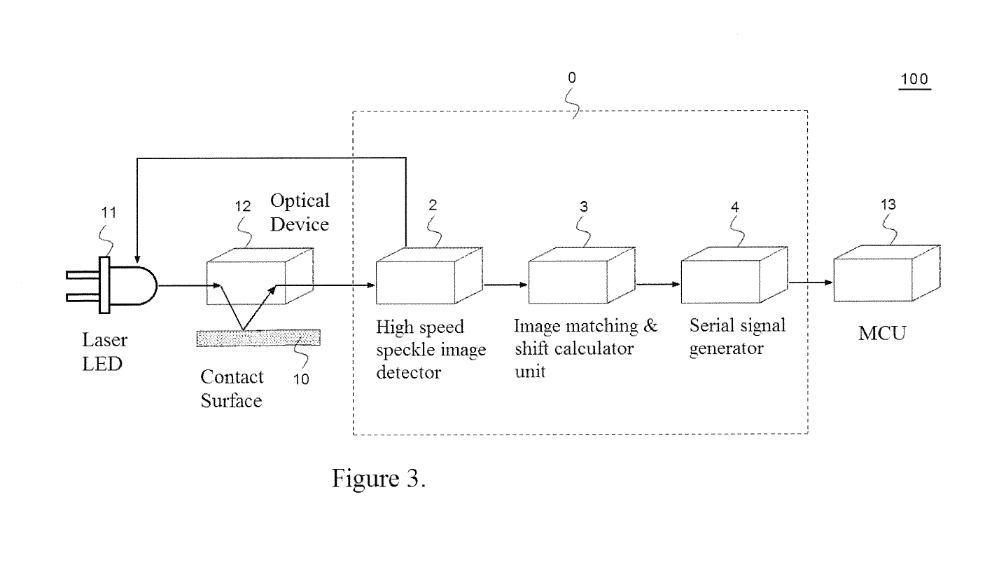

FIG. 3 illustrates an implementation of the electronic device in this invention. As the figure shows, the device (100) can be used as a scrollable controller or a high precision mouse device. It includes a laser LED (11), a contact surface (10), a high-speed image detection, capturing and matching unit with serial output (0), an optical device (12) and a microcontroller (13). The components (0), (11), and (13) are interconnected and installed together within the optical device (12). It obtains speckle patterns from diffuse reflections of the LED laser light source (11).

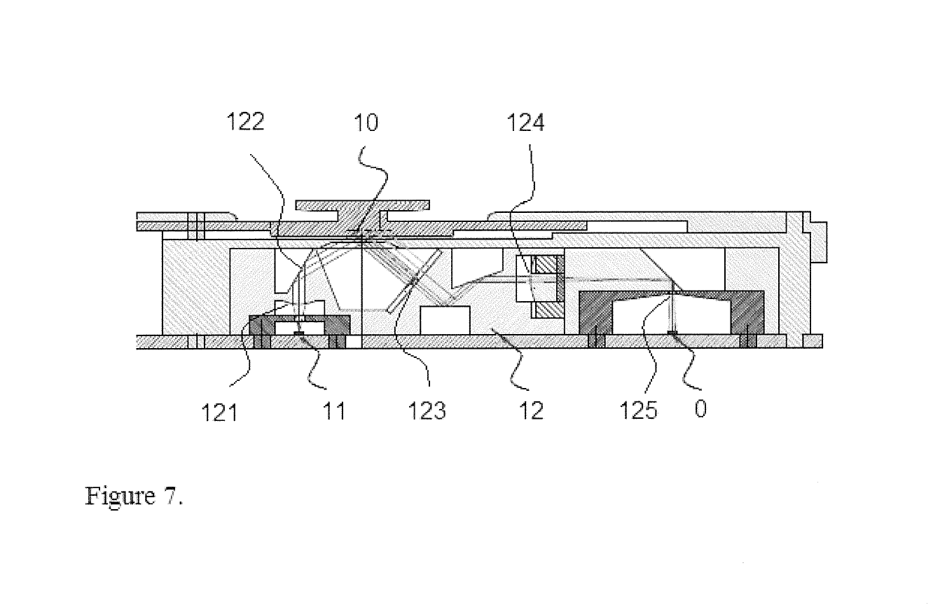

In this implementation, the optical device (12) is setup as shown in FIG. 7. The internal laser LED (11) emits infrared light with a wavelength of 850 nm. In order to account for variations among laser LEDs as well as unevenness for contact surface differences, the power of the laser is dynamically adjusted by the image detector. The produced light concentrates into collimated light as it passes through a convex lens, and subsequently reflects off the first reflective surface (122). It then produces diffuse reflections as it hits the contact surface (10) and enters the first aperture (123). The light is then directed by the second and third reflective surfaces towards the second convex lens (124) and the fourth reflexive surface. The final image-invariant speckle pattern emerges at the image detector after the light passes through the second aperture (125).

When a user scrolls over the contact surface (10) or moves the scrollable optical device (12), the action causes the contact surface to exhibit movement in the perspective of the optical device. As this occurs, the device will detect and capture successive image-invariant spectral patterns, upon which image matching can then be performed. The resulting image shift values between successive speckle patterns constitute the device's serial output. This output can then be utilized by the microcontroller.

The high speed image detector (2) deploys the optical sensor as an array of 22*22 optical diodes (M=22, L=22). The integrator array (21) contains 22 integrators working in parallel, one for each of the sub-arrays of optical diodes. Accordingly the voltage sampler circuit (22) contains 22 sample-hold units arranged in parallel. These all feed into the multiplexer (23) which carries out 23-to-1 signal multiplexing for the analogue-to-digital converter (24). Because the ADC has a sample rate of 4 M samples/sec, far faster than the rest of the circuit, the multiplexer allows one ADC to efficiently service the whole circuit. To achieve higher than 5000 frames/sec operation speed, the optical diode arrays, integrator array, and voltage sampler array operate in a pipelined way.

Each speckle-pixel data is got from a optical diode with 7.6 um*7.6 um physical layout size, and the integrating time for each pixel is less than 200 us. Thus the high speed image detector is capable of attaining a sampling rate of 5000 frames per second, or more. Information of each of these pixels is stored as a 256-level grey-scale value, within a 22*22 byte grey-scale memory unit (26).

The image matching and image shift calculation unit (3) contains an image duplicator (31) in its circuitry. The implementation of the copier has it taking a 10*10 byte block from the centre of the current image of speckle pattern, which is stored as a 22*22 byte grey-scale memory unit. It then copies the block into the central image memory (32) as the new Region of Interest (ROI). A subsequent grey-scale image can then be matched to the ROI by the image matching circuit (34). Because the ROI originally appears in the centre position (Xo, Yo) of the previous grey-scale image, at the next frame, there is a total of (22−10+1)*(22−10+1)=169 new possible positions where the image may have moved to.

To determine the image shift, image matcher uses the sum of absolute differences (SAD) method between the pixels to calculate the difference between each of these new possible positions and the original image. If the maximum value, SADmax, of these similarity matches exceeds the preset threshold value, then the pattern with SADmax similarity is considered a successful match to the ROI. Based on the coordinate (Xmax, Ymax) at which the desired pattern locates, the shifted distance from its previous position (Xmax-Xo, Ymax-Yo) is accumulated (35). At this point the process repeats, using the new ROI to search for a match in the next image again.

In this implementation, the serial signal generator (4) outputs the accumulated image shift values via two methods. The first is the synchronous A/B phase signals. This can output the image shift values at rates corresponding to the speed of the speckle image input, for instance, 200 us for 5000 frames/sec at the image detector. This is the suitable option for applications where synchronized updates is desired. The alternative is for the circuit to output its results using I2C signals. This provides an alternative for applications which only seek to read image shift values with asynchronous way.

1. A high speed image detection, capturing and matching device with serial output, comprising of:
an optical structure that restricts the path of the collimated lights;
an image-invariant optical speckle detection and capturing circuit;
an image matching unit; and
a serial signal output circuit.

2. Image invariant speckle pattern detection and capturing unit, comprising of:
an array of optical diodes as laser light sources;
an array of integrators;
an array of voltage samplers;
an analogue to digital converter;
a multiplexer;
a grey-scale memory block.

3. Image matching device with serial I2C and A/B phase output signals, comprising of:
an image copier;
a central image memory;
an image matching circuit;
an image shift calculator;
a clock signal generator; and
serial output signal generator.
